(19) United States
(12) Patent Application Publication
(10) Pub. No.: US 2026/0010083 A1
(43) Pub. Date: Jan. 8, 2026

(54) DEVICE AND METHOD FOR MEASURING A COMPONENT, AND LITHOGRAPHY SYSTEM

(71) Applicant: Carl Zeiss SMT GmbH, Oberkochen (DE)

(72) Inventors: Thomas WOERLE, Bopfingen (DE); Dominik GOLLMER, St. Johann (DE)

(21) Appl. No.: 19/326,126

(22) Filed: Sep. 11, 2025

Related U.S. Application Data
(63) Continuation of application No. PCT/EP2024/055129, filed on Feb. 28, 2024.

(30) Foreign Application Priority Data
Mar. 13, 2023 (DE) 10 2023 202 241.9

(51) Int. Cl. G03F 7/00

(52) U.S. Cl. CPC G03F 7/709; G03F 7/706849; G03F 7/70841

(57) ABSTRACT

An apparatus (1) for measuring a component (2) of a lithography system, having a vibration isolator device (3), a measuring system (4) mounted on the vibration isolator device and a supply device (5) supplying the measuring system via a data connection (6) transferring data between the supply device and the measuring system, a current connection (7) transferring electrical energy between the supply device and the measuring system, a gas connection (8) transferring a gas between the supply device and the measuring system, a liquid connection (9) transferring a liquid between the supply device and the measuring system, and/or a vacuum connection (10) transferring a vacuum between the supply device and the measuring system. A decoupling device (11) mechanically at least partially decouples the measuring system from the supply device at least during the measurement of the component.

### CROSS REFERENCE TO RELATED APPLICATIONS

This is a Continuation of International Application PCT/EP2024/055129, which has an international filing date of Feb. 28, 2024, and which claims the priority of German Patent Application 10 2023 202 241.9, filed Mar. 13, 2023. The disclosures of both applications are incorporated in their respective entireties into the present Continuation by reference.

### FIELD

The invention relates to an apparatus for measuring a component, in particular an optical component of a lithography system, having at least one vibration isolator device, a measuring system mounted on the at least one vibration isolator device and a supply device for supplying the measuring system via at least
one data connection for transferring data between the supply device and the measuring system and/or
one current connection for transferring electrical energy between the supply device and the measuring system and/or
one gas connection for transferring at least one gas between the supply device and the measuring system and/or
one liquid connection for transferring at least one liquid between the supply device and the measuring system and/or
one vacuum connection for transferring a vacuum between the supply device and the measuring system.

The invention also relates to a method for measuring a component, in particular an optical component, using a measuring system mounted in a vibration-damped manner, wherein a supply device supplies the measuring system via at least
one data connection for transferring data between the supply device and the measuring system and/or
one current connection for transferring electrical energy between the supply device and the measuring system and/or
one gas connection for transferring at least one gas between the supply device and the measuring system and/or
one liquid connection for transferring at least one liquid between the supply device and the measuring system and/or
one vacuum connection for transferring a vacuum between the supply device and the measuring system.

Furthermore, the invention relates to a lithography system, in particular a projection exposure apparatus for semiconductor lithography, having an illumination system with a radiation source and an optical unit which has at least one optical component.

In order to measure components, in particular optical components of lithography systems, measuring systems are used according to the prior art. The measuring systems known from the prior art require, for their operation, for example electrical energy (current), data and information, gas and/or liquids, such as water.

It is known from the prior art to use cables, hoses and screw connections in order to transfer media, in particular in order to supply current and transfer data, gas and liquids, between machine parts of a surroundings-side supply device and a vibration-isolated measuring system.

The cables and hoses used according to the prior art often have an inherent stiffness, in order to ensure static requirements, media loading and mounting safety, in particular with regard to buckling and crushing.

The cross sections and materials known from the prior art for the cables and hoses are so highly dimensioned that they exceed tuning frequencies of vibration isolator devices that support the measuring system.

It is therefore disadvantageous in the case of measuring systems known from the prior art, which are also referred to as measuring machine, that disruptive vibrations and forces are transmitted to the measuring system by the supply device and can then negatively influence a measuring process of the measuring system.

### BACKGROUND

The present invention includes an object of providing an apparatus for measuring a component, which avoids the disadvantages of the prior art and in particular allows reliable measurement of the component.

The present invention also includes an object of providing a method for measuring a component, which avoids the disadvantages of the prior art and in particular allows reliable measurement of the component.

The present invention furthermore includes an object of providing a lithography system which avoids the disadvantages of the prior art and in particular has reliably measured components.

These objects are addressed according to the invention by apparatuses, methods and a lithography system having the features specified in appended claims.

An apparatus according to the invention for measuring a component, in particular an optical component of a lithography system, comprises at least one vibration isolator device, a measuring system mounted on the at least one vibration isolator device and a supply device for supplying the measuring system via at least
one data connection for transferring data between the supply device and the measuring system and/or
one current connection for transferring electrical energy between the supply device and the measuring system and/or
one gas connection for transferring at least one gas between the supply device and the measuring system and/or
one liquid connection for transferring at least one liquid between the supply device and the measuring system and/or
one vacuum connection for transferring a vacuum between the supply device and the measuring system.

According to an aspect of the invention, a decoupling device is provided and configured to mechanically at least partially decouple the measuring system from the supply device at least during the measurement of the component.

An apparatus according to the invention allows media to be transferred in as contactless a manner as possible between the measuring system and the supply device or between machine parts, in particular in the case of highly sensitive measuring systems.

In the context of the invention, the term “media” or “media flows” should be understood to mean one, two, a plurality of or all of the media mentioned below, namely data, electrical energy, a gas or a plurality of different gases, a liquid or a plurality of different liquids, or a vacuum.

In the context of the invention, the term “connection” between the measuring system and the supply device should be understood to mean any of the connections below, namely a data connection or a current connection or a gas connection or a liquid connection or a vacuum connection, if the statements in the context of the invention do not explicitly relate to a specific connection. Accordingly, the term “connections” should be understood to mean one, two, a plurality of or all of the aforementioned connections.

An apparatus according to the invention is suitable for measuring a component, in particular an optical component. An apparatus according to the invention is very particularly suitable for measuring an optical component of a lithography system, in particular of a projection exposure apparatus for producing semiconductors.

In case of an apparatus according to the invention, cables, hoses and screw connections are preferably largely or completely omitted. This prevents transmission of disruptive vibrations to the measuring system or to the measuring system side of the apparatus.

In the case of an apparatus according to the invention, constructional solutions can be provided in order for media or media flows to be transferred contactlessly or at least with little contact to the sensitive measuring system. The constructional solutions in the case of this apparatus according to the invention are intended to reduce or avoid a direct mechanical connection between the isolated and the non-isolated sides of the apparatus for the transfer of media, preferably at least during the measurement of the component.

Provision may be made in the context of the invention for one, a plurality of or all of the media to be transferred without a direct mechanical connection from the supply device to the measuring system or for the decoupling device to be configured such that, at least during the measurement of the component, one of the connections, a plurality of the connections or all of the connections between the supply device and the measuring system are decoupled.

Provision may in particular be made in the context of the invention for two or more than two connections between the measuring system and the supply device to be mechanically decoupled by the decoupling device during the measurement of the component.

Provision may furthermore be made in the context of the invention for two or more than two media to be transferred contactlessly or without contact during the measurement of the component and/or for a transfer between the measuring system and the supply device to be omitted during the measurement of the component and/or for the measuring system to be supplied with the media by an internal storage unit of the measuring system.

In the context of the invention, two or more than two constructional solutions may be provided, allowing mechanical decoupling of a corresponding number of connections during the measurement of the component.

The decoupling device may in particular be configured to decouple direct mechanical connections between the measuring system and the supply device at least during the measurement of the component (i.e. in the operating state of the measuring system).

The decoupling device may be configured to mechanically at least partially, preferably completely, decouple one, a plurality of or all of the connections by an active measure at least during the measurement of the component. However, in the context of the invention, the decoupling device may also be configured so that one, a plurality of or all of the connections between the measuring system and the supply device are mechanically at least partially, preferably completely, decoupled continuously or permanently. The decoupling device may in particular also be configured such that it only mechanically couples one, a plurality of or all of the connections between the measuring system and the supply device when a supply of the measuring system is necessary and, at that point in time, no measurement of the component is being effected, for example the measuring system may have a storage unit for one, a plurality of or all of the media. The decoupling device may in particular be configured such that it actively mechanically at least partially decouples at least one of the connections and/or permanently or continuously contactlessly effects at least one of the connections and/or that at least one of the connections is only temporarily mechanically coupled when no measurement of the component is being effected, for example in order to supply a storage unit.

The decoupling device is preferably configured such that the connections are mechanically completely decoupled. However, for example for the transfer of a liquid, of a gas or of a vacuum, it may already be advantageous in relation to the prior art if the mechanical connection is at least partially decoupled, since these measures also reduce the transmission of vibrations.

In the context of the invention, the gas may in particular be air or a noble gas.

In the context of the invention, the transfer of a liquid may in particular concern water.

In the context of the invention, “the transfer of a vacuum between the supply device and the measuring system” should be understood in particular to mean that the supply device generates or maintains a vacuum in the measuring system.

Particularly advantageous configurations of the individual connections or of the possibilities for transferring individual media are illustrated below. These may be used in any combination.

Owing to the at least partial mechanical decoupling, an apparatus according to the invention also makes it possible for machine parts of the measuring system or of the supply device to be able to be exchanged more easily, preferably without cables, hoses and screw connections needing to be detached.

This apparatus according to the invention in particular makes it possible for cables and hoses, which have to have a corresponding inherent stiffness in order to meet the static requirements and for mounting safety (buckling, crushing, etc.), to be able to be omitted.

The decoupling device may in particular be of switchable design, in order to disconnect and reclose connections and/or have contact-free connections and/or have or produce low-contact connections. The decoupling device may in particular be configured to detach and reconnect plug-in connections, such that a connection between the measuring system and the supply device for the transfer of one of the media is disconnected or decoupled at least during the measurement of the component.

In the case of known measuring machines, cross sections and materials for the cables and hoses are also often dimensioned such that the cables and hoses exceed a tuning frequency of the vibration isolator devices that support the measuring system. The tuning frequency here describes, in particular, a first natural frequency. Typically, however, a cable harness and/or pipeline also has higher natural frequencies, which can then precisely in these frequency ranges introduce vibrations into the measuring system.

It is thus advantageous if in the case of an apparatus according to the invention the tuning frequency or the first natural frequency and/or higher natural frequencies and/or further vibration modes are used as decoupling design criterion.

In an advantageous development of an apparatus according to the invention, provision may be made for the decoupling device to be configured to form an at least partially wireless construction of the data connection.

A wireless or cable-free data connection or data transfer may in particular be effected via WLAN, Bluetooth and/or optical transmission methods.

The aforementioned data connections are suitable for the efficient transfer of signals between the supply device in the measuring system.

Here, in particular data for controlling the measuring system can be transferred from the supply device to the measuring system, whereas preferably measurement data, which the measuring system has gathered about the component, are transferred to the supply device for storage and further processing.

In an advantageous development of an apparatus according to the invention, provision may be made for the decoupling device to have an induction device which can be used to inductively transfer the electrical energy contactlessly at at least one point of the current connection.

In particular in the case of low decreases in power of the measuring system, current may be permanently transferred or supplied preferably contactlessly, in particular inductively. An inductive current transfer has the advantage that the current can be supplied contactlessly, as a result of which transmission of vibrations can advantageously be avoided.

In an advantageous development of an apparatus according to the invention, provision may be made for the decoupling device to have a gap seal and/or a labyrinth seal which is arranged at at least one point of the gas connection and/or of the liquid connection and/or of the vacuum connection.

The labyrinth seal and/or the gap seal facilitate a contactless media feed-through between the supply device and the measuring system to be realized.

A sealing effect of the labyrinth seal and/or of the gap seal is preferably based on an extension of a flow path of the gas and/or of the liquid and/or of the vacuum through a gap to be sealed, as a result of which a flow resistance is increased significantly. The path extension described above is preferably achieved by interlocking or meshing of shaped elements.

Preferably, the labyrinth seal and/or the gap seal are designed so that no flow separation, which can lead to undesirable vibrations, occurs in the medium.

It has proven to be advantageous if the gas connection and/or the liquid connection is effected with a sealing system which acts at least with little contact, preferably contactlessly, such that the vibration of the connection, compared with a direct mechanical connection, is minimized. For this, labyrinth seals and gap seals are particularly suitable.

In the context of the invention, the vacuum connection may be understood in particular to mean a connection by which residual gas is conveyed out of the measuring system toward the supply device, as a result of which a vacuum environment can be created in a region of the measuring system. The resultant gas flow is accordingly directed from the measuring system to the supply device. By contrast, in the case of the gas connection described above, the gas flow is preferably directed from the supply device to the measuring system.

In an advantageous development of an apparatus according to the invention, provision may be made for the gap seal and/or the labyrinth seal to have a sealing air device for increasing the sealing effect.

The sealing effect of the labyrinth seal or of the gap seal can be further increased by the sealing air assistance. The use of sealing air is one possibility for sealing a cavity formed by the gas connection and/or the vacuum connection with the aid of an air overpressure and/or a gas overpressure and/or sealing-air suction removal and/or gas suction removal and improves the contact-free sealing effect. Provision may be made for the flow properties of the sealing air to be selected so that production of vibrations in a region of the labyrinth seal and/or of the gap seal by the sealing air is avoided.

In an advantageous development of an apparatus according to the invention, provision may be made for the decoupling device to be arranged in an interface region between the supply device and the measuring system.

Arranging the decoupling device in an individual interface region, i.e. spatially concentrating the individual connections in the interface region, has the advantage that it can preferably be mounted and/or isolated in a particularly reliable manner.

In an advantageous development of an apparatus according to the invention, provision may be made for the decoupling device to have an actuated movement mechanism.

If the connections between the measuring system and the supply device are produced and/or disconnected with the actuated movement mechanism, this can advantageously be effected rapidly. Rapid production and/or rapid disconnection of the connection has the advantage in the case of measuring systems that a process time of a measuring process or a processing time can advantageously be kept low.

In an advantageous development of an apparatus according to the invention, provision may be made for the decoupling device to be configured to disconnect and/or to connect the data connection and/or the current connection and/or the gas connection and/or the liquid connection and/or the vacuum connection.

A temporary connection and/or a temporary supply of media for a duration of the sensitive measuring process has the advantage that complex contactless connections or transmission methods can be omitted as a result.

In particular, provision may be made for the decoupling device to disconnect the data connection and/or the current connection and/or the gas connection and/or the liquid connection and/or the vacuum connection during or before the start of a measuring operation of the measuring system. After the measuring process has ended, the decoupling device reconnects the data connection and/or the current connection and/or the gas connection and/or the liquid connection and/or the vacuum connection to the supply device, such that the measuring system can be supplied.

The decoupling device may in particular be configured to disconnect and/or to connect a mechanical connection between the supply device and the measuring system.

In an advantageous development of an apparatus according to the invention, provision may be made for the decoupling device to have at least one data carrier and/or at least one electrical charge storage unit and/or at least one gas storage unit and/or at least one liquid container and/or at least one vacuum accumulator device.

An accumulator and/or a storage unit, such as a capacitor, may be provided as part of the measuring system and/or on the measuring system side. In particular, provision may be made for the measuring-system-side accumulator or storage unit to be charged with the required amount of electrical energy before the measuring process.

An apparatus according to the invention can accordingly be in two operating modes, which can also at the same time be realized in one and the same apparatus.

The first operating mode is a permanent mode, in which the media, electrical energy or current and the data, are transferred continuously, but contactlessly.

The second operating mode is a temporary mode, in which storage systems (or only one storage system) in the apparatus are charged before the start of the measuring process, such that the measuring system can function autonomously during a measuring process.

The two operating modes, i.e. the temporary operating mode and the permanent operating mode, can be provided for different measuring tasks. In particular, the selection of the operating mode may be made in a targeted manner in dependence on the media to be provided and a decrease in demand of the measuring system with respect to the media to be provided or the electrical energy to be provided.

The above-described embodiments of an apparatus make it possible to realize a measuring apparatus for measuring components, preferably optical components, of a lithography apparatus. In the case of the apparatus, media, such as electrical energy or data, e.g. electromagnetic signals, are transferred to the measuring system preferably contactlessly, that is to say without mechanical contact connection. This apparatus according to the invention and the advantageous developments thereof allow, in particular, vibrations to be minimized on the measuring system in the operating states thereof, preferably during the measurement of the optical component. In the case of the apparatus, provision may be made for liquids and/or gases to be transferred not entirely contactlessly, but at least in a vibration-minimized manner, through special seals from the supply device to the measuring system and/or for at least one storage unit, integrated in the measuring system, or storage system which supplies the measuring system during the measurement of the optical components to be filled.

In an advantageous development of an apparatus according to the invention, provision may be made for the data connection and/or the current connection and/or the gas connection and/or the liquid connection and/or the vacuum connection to have such a low stiffness that transmission of vibrations from the supply device to the measuring system is at least largely suppressed.

Instead of a completely contactless transfer of the media, it is also feasible to provide a connection, e.g. a connecting line, the stiffness of which is selected to be so low that vibrations are not transmitted or only to an insignificant extent.

For example, in order to transfer electrical energy, instead of an insulated cable, it is feasible to provide merely a thin wire strand which preferably has an insulating coating.

In an advantageous development of an apparatus according to the invention, provision may be made for the data connection and/or the current connection and/or the gas connection and/or the liquid connection and/or the vacuum connection to have a stiffness of 0.1 N/mm to 100 N/mm, preferably 0.1 N/mm to 50 N/mm, further preferably 0.2 N/mm to 10 N/mm, in particular 0.2 N/mm to 2 N/mm.

The stiffness values described above should preferably be considered in connection with a mass or an isolated structure or the measuring system.

An isolated mass for the isolated structure or the measuring system may, for example, be 10 kg. A stiffness of c=0.1 N/mm here results in a first natural frequency or tuning frequency of 0.5 Hz.

An isolated mass for the isolated structure or the measuring system may, for example, be 10,000 kg. A stiffness of c=100 N/mm here also results in a first natural frequency or tuning frequency of 0.5 Hz.

Correspondingly, larger or smaller machines can have greater or smaller stiffnesses and masses. Preferably, the first natural frequency ω can be ascertained via the formula

$$ω = \sqrt{\frac{c}{m}} ,$$

where c describes the stiffness and m the isolated mass.

The inventors have identified that, at a stiffness with the aforementioned values, vibrations which impair the measuring process are not transferred by the data connection and/or the current connection and/or the gas connection and/or the liquid connection and/or the vacuum connection.

Provision may also be made for the measuring system to be arranged in an isolation box. In particular, the isolation box may be of soundproof and/or vibration-isolated design. This makes it possible to decrease and/or reduce transmission of airborne sound to the measuring system. Here, the isolation box can be considered part of the decoupling device.

Provision may be made for the decoupling device to be in the form of a plug-in module and/or connecting module.

The invention also relates to a method having the features specified in the claims.

In the case of a method according to the invention for measuring a component, in particular an optical component, using a measuring system mounted in a vibration-damped manner, a supply device supplies the measuring system via at least
one data connection for transferring data between the supply device and the measuring system and/or
one current connection for transferring electrical energy between the supply device and the measuring system and/or
one gas connection for transferring at least one gas between the supply device and the measuring system and/or
one liquid connection for transferring at least one liquid between the supply device and the measuring system and/or
one vacuum connection for transferring a vacuum between the supply device and the measuring system.

According to an aspect of the invention, the measuring system is mechanically at least partially decoupled from the supply device at least during the measurement of the component.

Provision may be made for direct mechanical connections between the measuring system and the supply device to be decoupled at least during the measurement of the component.

Provision may be made for the at least partial mechanical decoupling to be achieved by complete mechanical decoupling or disconnection of one or all of the connections, that is to say the data connection and/or the current connection and/or the gas connection and/or the liquid connection and/or the vacuum connection.

As an alternative or in addition, provision may be made for the at least partial mechanical decoupling to be achieved by a reduction in the capability of one or all of the connections, that is to say the data connection and/or the current connection and/or the gas connection and/or the liquid connection and/or the vacuum connection, to transmit mechanical excitations, in particular vibrations.

A method according to the invention has the advantage that a particularly reliable measurement of the component with the measuring system is made possible, since the measuring system is protected, at least during the measuring process, against vibrations which impair the measurement accuracy.

In an advantageous development of this method according to the invention, provision may be made for data to be transferred wirelessly via the data connection.

A wireless transfer of data can be realized in a particularly reliable and simple manner using established systems, such as WLAN and/or Bluetooth.

In an advantageous development of this method according to the invention, provision may be made for the electrical energy to be transferred at least partially inductively via the current connection.

An inductive transfer of the electrical energy can be effected contactlessly and is suitable in particular for measuring processes which require only a small decrease in power of the measuring system.

In an advantageous development of this method according to the invention, provision may be made for the at least one gas and/or the at least one liquid and/or the at least one vacuum to be transferred at at least one point of the gas connection and/or of the liquid connection and/or of the vacuum connection via a gap seal and/or a labyrinth seal.

Using a gap seal and/or a labyrinth seal in the transfer of the gas, the liquid and/or the vacuum has the advantage that contact-free sealing is feasible with the labyrinth seal and/or the gap seal.

In particular, the use of the gap seal and/or the labyrinth seal is suitable if the used pressures of the gas and/or the liquid or the acting negative pressure in the case of the vacuum are/is limited. Specific values for the used pressures of the gas and/or the liquid or the acting negative pressure in the case of the vacuum can be determined so that the occurrence of turbulence is avoided or is at least largely avoided.

In an advantageous development of this method according to the invention, provision may be made for the data connection and/or the current connection and/or the gas connection and/or the liquid connection and/or the vacuum connection to be disconnected before the measurement of the component and/or reconnected after the measurement of the component.

This method may be carried out in a temporary operating mode (which in the context of the invention is also referred to as second operating mode) and/or in a permanent operating mode (which in the context of the invention is also referred to as first operating mode).

In the permanent operating mode, the data, the electrical energy, the gas, the liquid and/or the vacuum are transferred permanently between the measuring system and the supply device, even during the measuring process.

In the temporary operating mode, provision may be made for the measuring system to be temporarily connected to the supply device and for the connections between the measuring system and the supply device to be disconnected or capped in particular during the measurement of the component.

In an advantageous development of this method according to the invention, provision may be made for the measuring system to be operated partially or completely autonomously during a measurement of the component.

If the measuring system is operated partially or completely autonomously, the respective direct connections between the measuring system and the supply device can thus be partially or completely disconnected during the measurement of the component.

For example, it may be provided that, from the beginning of the measurement, the measuring system is evacuated and, after complete evacuation, the measuring system is disconnected from a vacuum pump of the supply device and closed in a vacuum-tight manner. It is feasible for the quality of the acting vacuum to remain in a tolerable range for the time of the measurement.

Similarly, provision may be made, from the beginning of the measurement, for the measuring system to be flooded with a gas, in particular a noble gas, the gas concentration during a time of the measurement remaining in a sufficient and tolerable range.

In an advantageous development of this method according to the invention, it may be provided that, before the measurement of the component, at least one data carrier and/or at least one electrical charge storage unit and/or at least one gas storage unit and/or at least one liquid container and/or at least one vacuum accumulator device is loaded via the data connection and/or the current connection and/or the gas connection and/or the liquid connection and/or the vacuum connection.

Storage devices (in the context of the invention also referred to as storage unit/storage system) are particularly advantageous for performing the method in the temporary operating mode. For example, provision may be made for the electrical charge storage unit to be loaded with high power outside the measurement time a cable connection. The measuring system then benefits from the stored energy during the measurement.

In an advantageous development of this method according to the invention, it may be provided that, during a measurement of the component, the measuring system is supplied at least partially by the data carrier and/or the electrical charge storage unit and/or the gas storage unit and/or the liquid container and/or the vacuum accumulator device.

Provision may be made for the above-described storage devices, during the operation of the measuring system or during the measurement of the component, to assist the performance of the method in the permanent operation mode by the temporary operating mode. For example, it may be provided that, in order to supplement the transfer of electrical energy by induction, in particular when power peaks are present, electrical energy from the electrical charge storage unit is also used.

Provision may accordingly be made for combined or simultaneous use of both operating modes, feasibly also only for individual media.

Provision may be made in the case of a measuring operation in which no gas or no air is required for a relatively stiff gas connection at the decoupling device or at an interface surface or an interface region to be disconnected. At the same time, provision may be made for a cable connection with a relatively low stiffness to permanently remain. The interface region is preferably arranged between the supply device and the measuring system or the interface surface is preferably formed between the supply device and the measuring system.

An aspect of the invention also relates to a lithography system.

A lithography system according to the invention, in particular a projection exposure apparatus for semiconductor lithography, comprises an illumination system with a radiation source and an optical unit which has at least one optical component. According to this aspect of the invention, at least one of the optical components is at least partially measured with the above-described apparatus according to the invention and/or with the above-described method according to the invention.

A lithography system according to the invention has the advantage that its components, in particular its optical components, which are also referred to as optical elements, are measured in a particularly reliable manner. Preferably, the optical components are mirrors, lens elements or a collector. In this way, this lithography system according to the invention can be used to produce semiconductor products which are formed in a particularly reliable manner.

An apparatus according to the invention is suitable in particular for use as measuring machine for measuring projection optical units of lithography systems.

Features described in conjunction with one of the subjects of the invention, specifically given by apparatuses according to the invention, methods according to the invention, or lithography systems according to the invention, are also advantageously implementable for the other subjects of the invention. Likewise, advantages specified in conjunction with one of the subjects of the invention can also be understood in relation to the other subjects of the invention.

Additionally, it should be noted that terms such as “comprising”, “having”, or “with” do not exclude other features or steps. Furthermore, terms such as “a(n)” or “the” which indicate single steps or features do not exclude a plurality of features or steps—and vice versa.

However, in a puristic embodiment of the invention, provision may also be made for the features introduced in the invention using the terms “comprising”, “having”, or “with” to be an exhaustive enumeration. Accordingly, one or more enumerations of features can be considered to be exhaustive within the scope of the invention, for example respectively considered for each claim. For example, the invention can consist exclusively of the features specified in the independent apparatus claim.

It should be noted that designations such as “first” or “second”, etc. are used predominantly to be able to distinguish between respective apparatus or method features and are not necessarily intended to indicate that features require one another or are related to one another.

The vibration isolator device provided according to the invention, the supply device and the decoupling device can also be provided and configured to be used for a lithography system itself. This means that apparatuses according to the invention can be used for the lithography system itself. This constitutes an independent (second) aspect of the invention, it being feasible for this purpose for reference to also be made directly or analogously to the aforementioned and subsequent configurations of the described apparatuses according to the invention and of the described methods according to the invention.

The second aspect of the invention can be characterized as follows:

An apparatus for a lithography system having at least one vibration isolator device, the lithography system (or a component of the lithography system, in particular a projection system or an illumination optical unit or an exposure system or an illumination system) mounted on the at least one vibration isolator device and a supply device for supplying the lithography system (or a component of the lithography system, in particular a projection system or an exposure system) via at least
one data connection for transferring data between the supply device and the lithography system (or a component of the lithography system, in particular a projection system or an exposure system) and/or
one current connection for transferring electrical energy between the supply device and the lithography system (or a component of the lithography system, in particular a projection system or an exposure system) and/or
one gas connection for transferring at least one gas between the supply device and the lithography system (or a component of the lithography system, in particular a projection system or an exposure system) and/or
one liquid connection for transferring at least one liquid between the supply device and the lithography system (or a component of the lithography system, in particular a projection system or an exposure system) and/or
one vacuum connection for transferring a vacuum between the supply device and the lithography system (or a component of the lithography system, in particular a projection system or an exposure system),
   characterized in that
   a decoupling device is provided and configured to mechanically at least partially, preferably completely, decouple the lithography system (or a component of the lithography system, in particular a projection system or an exposure system) from the supply device at least during a predefinable operation (for example during maintenance or during operation or during an adjustment).

A corresponding method according to the invention for the second aspect of the invention can be characterized as follows:

A method for a lithography system having at least one vibration isolator device on which the lithography system (or a component of the lithography system, in particular a projection system or an exposure system) is mounted, wherein a supply device supplies the lithography system (or a component of the lithography system, in particular a projection system or an exposure system) via at least
one data connection for transferring data between the supply device and the lithography system (or a component of the lithography system, in particular a projection system or an exposure system) and/or
one current connection for transferring electrical energy between the supply device and the lithography system (or a component of the lithography system, in particular a projection system or an exposure system) and/or
one gas connection for transferring at least one gas between the supply device and the lithography system (or a component of the lithography system, in particular a projection system or an exposure system) and/or
one liquid connection for transferring at least one liquid between the supply device and the lithography system (or a component of the lithography system, in particular a projection system or an exposure system) and/or
one vacuum connection for transferring a vacuum between the supply device and the lithography system (or a component of the lithography system, in particular a projection system or an exposure system),
   characterized in that
   the lithography system (or a component of the lithography system, in particular a projection system or an exposure system) is mechanically at least partially, preferably completely, decoupled from the supply device at least during a predefinable operation (for example during maintenance or during operation or during an adjustment).

The use of the apparatus and of the method for the lithography system itself allows media to be transferred in as contactless a manner as possible between the lithography system (or a component of the lithography system, in particular a projection system or an exposure system) and the supply device at least during a predefined operation, as a result of which disruptive vibrations and forces which can negatively influence the operation are avoided.

The independent claims, i.e. claims defining an apparatus for measuring a component having at least one vibration isolator device, a measuring system mounted on the at least one vibration isolator device and a supply device for supplying the measuring system and, respectively, claims defining a method for measuring a component using a measuring system mounted in a vibration-damped manner, wherein a supply line supplies the measuring system, can in a specific embodiment also be understood such that the measuring system is the lithography system (or a component of the lithography system, in particular a projection system or an illumination optical unit or an exposure system or an illumination system), which is configured and provided to produce a semiconductor and is operated correspondingly for this purpose.

Exemplary embodiments of the invention will be described in more detail below with reference to the drawing.

The figures each show preferred exemplary embodiments in which individual features of the present invention are illustrated in combination with one another. Features of an exemplary embodiment are also implementable independently of the other features of the same exemplary embodiment, and may readily be combined accordingly by a person skilled in the art to form further viable combinations and sub-combinations with features of other exemplary embodiments.

In the figures, functionally analogous or identical elements are given the same reference signs.

### BRIEF DESCRIPTION OF THE DRAWINGS

In the figures:

FIG. 1 shows a meridional section of an extreme ultraviolet (EUV) projection exposure apparatus;

FIG. 2 shows a deep ultraviolet (DUV) projection exposure apparatus;

FIG. 3 shows a schematic illustration of a feasible embodiment of an apparatus according to the invention or of a method according to the invention;

FIG. 4 shows a schematic illustration of a feasible embodiment of a transfer device;

FIG. 5 shows a schematic illustration of a further feasible embodiment of an apparatus according to the invention or of a method according to the invention; and

FIG. 6 shows a block diagram-like illustration of a feasible embodiment of a method according to the invention.

### DETAILED DESCRIPTION

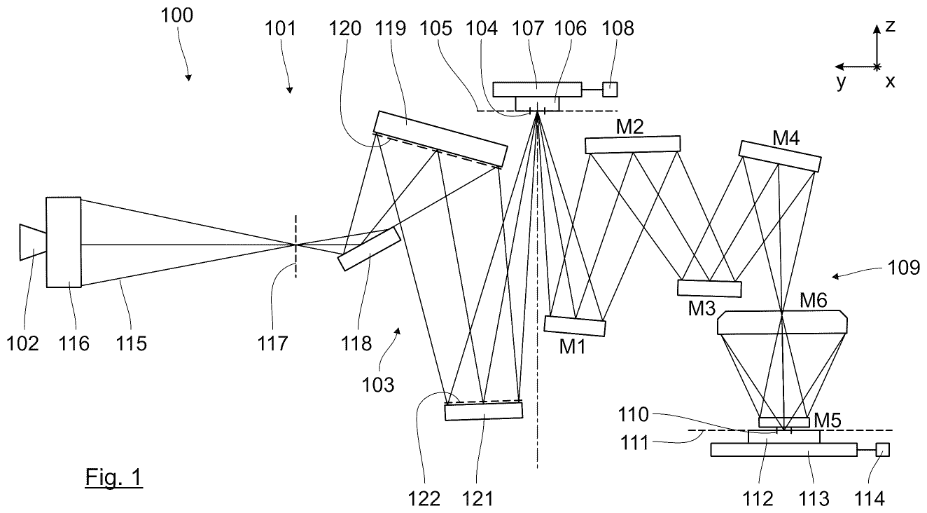

With reference to FIG. 1, the predominant component parts of a microlithographic extreme ultraviolet (EUV) projection exposure apparatus 100 as an example of a lithography system are initially described below in exemplary fashion. The description of the basic construction of the EUV projection exposure apparatus 100 and of the component parts thereof should not be interpreted restrictively here.

An illumination system 101 of the EUV projection exposure apparatus 100 comprises, besides a radiation source 102, an illumination optical unit 103 for the illumination of an object field 104 in an object plane 105. What is exposed here is a reticle 106 arranged in the object field 104. The reticle 106 is held by a reticle holder 107. The reticle holder 107 is displaceable in particular in a scanning direction via a reticle displacement drive 108.

FIG. 1 depicts a Cartesian xyz-coordinate system for illustrative purposes. The x-direction runs perpendicularly into the plane of the drawing. The y-direction runs horizontally, and the z-direction runs vertically. In FIG. 1, the scanning direction runs in the y-direction. The z-direction runs perpendicularly to the object plane 105.

The EUV projection exposure apparatus 100 comprises a projection optical unit 109. The projection optical unit 109 serves for imaging the object field 104 into an image field 110 in an image plane 111. The image plane 111 runs parallel to the object plane 105. Alternatively, an angle between the object plane 105 and the image plane 111 that differs from 0° is also feasible.

A structure on the reticle 106 is imaged onto a light-sensitive layer of a wafer 112 arranged in the region of the image field 110 in the image plane 111. The wafer 112 is held by a wafer holder 113. The wafer holder 113 is displaceable in particular in the y-direction via a wafer displacement drive 114. The displacement on the one hand of the reticle 106 by the reticle displacement drive 108 and on the other hand of the wafer 112 by the wafer displacement drive 114 may be synchronized with one another.

The radiation source 102 is an EUV radiation source. The radiation source 102 emits in particular EUV radiation 115, which in the following text is also referred to as used radiation or illumination radiation. In particular, the used radiation 115 has a wavelength in the range between 5 nm and 30 nm. The radiation source 102 can be a plasma source, for example an LPP source (“laser produced plasma”) or a GDPP source (“gas discharge produced plasma”). It may also be a synchrotron-based radiation source. The radiation source 102 can be a free electron laser (FEL).

The illumination radiation 115 emanating from the radiation source 102 is focused by a collector 116. The collector 116 can be a collector with one or more ellipsoidal and/or hyperboloidal reflection surfaces. The at least one reflection surface of the collector 116 can be impinged upon by the illumination radiation 115 with grazing incidence (GI), i.e. with angles of incidence greater than 45°, or with normal incidence (NI), i.e. with angles of incidence less than 45°. The collector 116 can be structured and/or coated, firstly, for optimizing its reflectivity for the used radiation 115 and, secondly, for suppressing extraneous light.

Downstream of the collector 116, the illumination radiation 115 propagates through an intermediate focus in an intermediate focal plane 117. The intermediate focal plane 117 can constitute a separation between a radiation source module, comprising the radiation source 102 and the collector 116, and the illumination optical unit 103.

The illumination optical unit 103 comprises a deflection mirror 118 and, disposed downstream thereof in the beam path, a first facet mirror 119. The deflection mirror 118 can be a planar deflection mirror or alternatively a mirror with a beam-influencing effect going beyond the pure deflection effect. As an alternative or in addition, the deflection mirror 118 may be in the form of a spectral filter that separates a used light wavelength of the illumination radiation 115 from extraneous light of a wavelength deviating therefrom. If the first facet mirror 119 is arranged in a plane of the illumination optical unit 103 which is optically conjugate to the object plane 105 as a field plane, it is also referred to as a field facet mirror. The first facet mirror 119 comprises a multiplicity of individual first facets 120, which are also referred to below as field facets. Only a few of these facets 120 are illustrated in FIG. 1 by way of example.

The first facets 120 may be in the form of macroscopic facets, in particular rectangular facets or facets with an arc-shaped edge contour or part-circle-shaped edge contour. The first facets 120 may be in the form of planar facets or alternatively of convexly or concavely curved facets.

As is known for example from DE 10 2008 009 600 A1, the first facets 120 themselves may each also be composed of a multiplicity of individual mirrors, in particular a multiplicity of micromirrors. The first facet mirror 119 may be in the form of a microelectromechanical system (MEMS system) in particular. For details, reference is made to DE 10 2008 009 600 A1.

The illumination radiation 115 travels horizontally, i.e. in the y-direction, between the collector 116 and the deflection mirror 118.

In the beam path of the illumination optical unit 103, a second facet mirror 121 is disposed downstream of the first facet mirror 119. If the second facet mirror 121 is arranged in a pupil plane of the illumination optical unit 103, it is also referred to as a pupil facet mirror. The second facet mirror 121 may also be arranged at a distance from a pupil plane of the illumination optical unit 103. In this case, the combination of the first facet mirror 119 and the second facet mirror 121 is also referred to as a specular reflector. Specular reflectors are known from US 2006/0132747 A1, EP 1 614 008 B1 and U.S. Pat. No. 6,573,978.

The second facet mirror 121 comprises a plurality of second facets 122. In the case of a pupil facet mirror, the second facets 122 are also referred to as pupil facets.

The second facets 122 may also be macroscopic facets, which may for example have a round, rectangular or hexagonal boundary, or may alternatively be facets composed of micromirrors. In this regard, reference is also made to DE 10 2008 009 600 A1.

The second facets 122 may have planar or, alternatively, convexly or concavely curved reflection surfaces.

The illumination optical unit 103 thus forms a doubly faceted system. This basic principle is also referred to as fly's eye integrator.

It may be advantageous to arrange the second facet mirror 121 not exactly in a plane that is optically conjugate to a pupil plane of the projection optical unit 109.

The individual first facets 120 are imaged into the object field 104 using the second facet mirror 121. The second facet mirror 121 is the last beam-shaping mirror or else actually the last mirror for the illumination radiation 115 in the beam path upstream of the object field 104.

In a further embodiment (not illustrated) of the illumination optical unit 103, a transfer optical unit contributing in particular to the imaging of the first facets 120 into the object field 104 may be arranged in the beam path between the second facet mirror 121 and the object field 104. The transfer optical unit can have exactly one mirror or alternatively two or more mirrors, which are arranged one behind the other in the beam path of the illumination optical unit 103. In particular, the transfer optical unit can comprise one or two normal incidence mirrors (NI mirrors) and/or one or two grazing incidence mirrors (GI mirrors).

In the embodiment shown in FIG. 1, the illumination optical unit 103 has exactly three mirrors downstream of the collector 116, specifically the deflection mirror 118, the field facet mirror 119 and the pupil facet mirror 121.

In a further embodiment of the illumination optical unit 103, the deflection mirror 118 can also be omitted, and so the illumination optical unit 103 can then have exactly two mirrors downstream of the collector 116, specifically the first facet mirror 119 and the second facet mirror 121.

The imaging of the first facets 120 into the object plane 105 via the second facets 122 or using the second facets 122 and a transfer optical unit is, as a rule, only approximate imaging.

The projection optical unit 109 comprises a plurality of mirrors Mi, which are numbered in accordance with their arrangement in the beam path of the EUV projection exposure apparatus 100.

In the example illustrated in FIG. 1, the projection optical unit 109 comprises six mirrors M1 to M6. Alternatives with four, eight, ten, twelve or a different number of mirrors Mi are also feasible. The second-last mirror M5 and the last mirror M6 each have a passage opening for the illumination radiation 115. The projection optical unit 109 is a doubly obscured optical unit. The projection optical unit 109 has an image-side numerical aperture which is greater than 0.5 and may also be greater than 0.6 and may for example be 0.7 or 0.75.

Reflection surfaces of the mirrors Mi may be in the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optical unit 103, the mirrors Mi may have highly reflective coatings for the illumination radiation 115. These coatings may be designed as multilayer coatings, in particular with alternating layers of molybdenum and silicon.

The projection optical unit 109 has a large object-image shift in the y-direction between a y-coordinate of a center of the object field 104 and a y-coordinate of the center of the image field 110. In the y-direction, this object-image shift may be of approximately the same size as a z-distance between the object plane 105 and the image plane 111.

In particular, the projection optical unit 109 may have an anamorphic design. In particular, it has different imaging scales βx, βy in the x- and y-directions. The two imaging scales βx, βy of the projection optical unit 109 are preferably (βx, βy)=(+/−0.25, +/−0.125). A positive imaging scale β means imaging without image inversion. A negative sign for the imaging scale β means imaging with image inversion.

The projection optical unit 109 thus leads to a reduction in size with a ratio of 4:1 in the x-direction, i.e. in a direction perpendicular to the scanning direction.

The projection optical unit 109 leads to a reduction in size of 8:1 in the y-direction, i.e. in the scanning direction.

Other imaging scales are also feasible. Imaging scales with the same signs and the same absolute values in the x- and y-directions, for example with absolute values of 0.125 or 0.25, are also feasible.

The number of intermediate image planes in the x-direction and in the y-direction in the beam path between the object field 104 and the image field 110 may be the same or may be different, depending on the embodiment of the projection optical unit 109. Examples of projection optical units with different numbers of such intermediate images in the x- and y-directions are known from US 2018/0074303 A1.

In each case, one of the pupil facets 122 is assigned to exactly one of the field facets 120 for the purpose of forming a respective illumination channel for illuminating the object field 104. This may in particular result in illumination according to the Köhler principle. The far field is decomposed into a multiplicity of object fields 104 with the aid of the field facets 120. The field facets 120 create a plurality of images of the intermediate focus on the pupil facets 122 respectively assigned thereto.

The field facets 120 are each imaged by an assigned pupil facet 122 onto the reticle 106 in a manner overlaid on one another in order to illuminate the object field 104. The illumination of the object field 104 is in particular of maximum homogeneity. It preferably has a uniformity error of less than 2%. Field uniformity can be attained by overlaying different illumination channels.

The illumination of the entrance pupil of the projection optical unit 109 may be defined geometrically through an arrangement of the pupil facets. The intensity distribution in the entrance pupil of the projection optical unit 109 may be set by selecting the illumination channels, in particular the subset of the pupil facets which guide light. This intensity distribution is also referred to as illumination setting.

A likewise preferred pupil uniformity in the region of portions of an illumination pupil of the illumination optical unit 103 that are illuminated in a defined manner can be attained by a redistribution of the illumination channels.

Further aspects and details of the illumination of the object field 104 and, in particular, of the entrance pupil of the projection optical unit 109 are described below.

The projection optical unit 109 may have in particular a homocentric entrance pupil, which may either be accessible or be inaccessible.

The entrance pupil of the projection optical unit 109 generally cannot be illuminated exactly with the pupil facet mirror 121. The aperture rays often do not intersect at a single point in the event of imaging by the projection optical unit 109 that telecentrically images the center of the pupil facet mirror 121 onto the wafer 112. However, it is feasible to find an area in which the spacing of the aperture rays, which is determined in pairs, becomes minimal. This area represents the entrance pupil or an area conjugate thereto in real space. In particular, this area exhibits a finite curvature.

It may be the case that the projection optical unit 109 has different positions of the entrance pupil for the tangential beam path and for the sagittal beam path. In this case, an imaging element, in particular an optical structural element of the transfer optical unit, should be provided between the second facet mirror 121 and the reticle 106. With the aid of this optical structural element, it is feasible to take account of the different position of the tangential entrance pupil and the sagittal entrance pupil.

In the arrangement of the components of the illumination optical unit 103 illustrated in FIG. 1, the pupil facet mirror 121 is arranged in an area conjugate to the entrance pupil of the projection optical unit 109. The first field facet mirror 119 is tilted with respect to the object plane 105. The first facet mirror 119 has a tilt with respect to an arrangement plane defined by the deflection mirror 118.

The first facet mirror 119 has a tilt with respect to an arrangement plane defined by the second facet mirror 121.

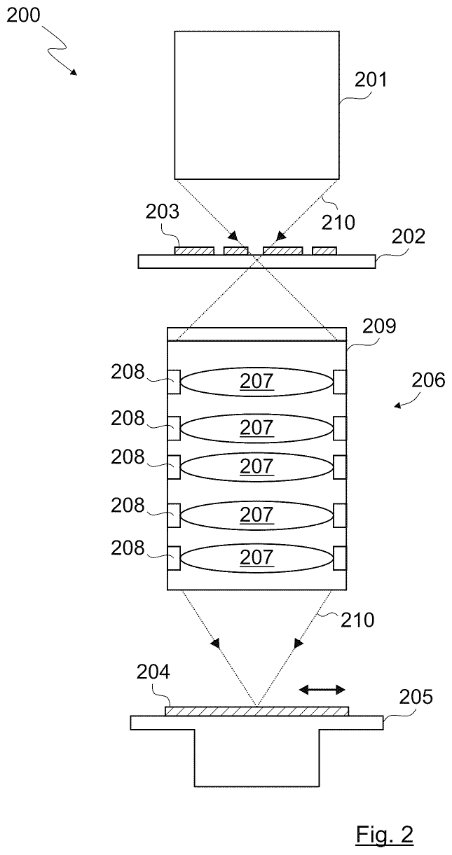

FIG. 2 shows an exemplary deep ultraviolet (DUV) projection exposure apparatus 200. The DUV projection exposure apparatus 200 comprises an illumination system 201, a device known as a reticle stage 202 for receiving and exactly positioning a reticle 203 by which the later structures on a wafer 204 are determined, a wafer holder 205 for holding, moving and exactly positioning the wafer 204, and an imaging device, specifically a projection optical unit 206, with a plurality of optical components, in particular lens elements 207, which are held via mounts 208 in a lens housing 209 of the projection optical unit 206.

As an alternative or in addition to the lens elements 207 illustrated, provision may be made of various refractive, diffractive and/or reflective optical elements, inter alia also mirrors, prisms, terminating plates, and the like.

The basic functional principle of the DUV projection exposure apparatus 200 makes provision for the structures introduced into the reticle 203 to be imaged onto the wafer 204.

The illumination system 201 provides a projection beam 210 in the form of electromagnetic radiation, which is required for the imaging of the reticle 203 onto the wafer 204. The source used for this radiation may be a laser, a plasma source, or the like. The radiation is shaped in the illumination system 201 by optical elements such that the projection beam 210 has the desired properties with regard to diameter, polarization, shape of the wavefront, and the like when it is incident on the reticle 203.

An image of the reticle 203 is created and transferred from the projection optical unit 206 onto the wafer 204 with the projection optical unit 206 in an appropriately reduced form. In this case, the reticle 203 and the wafer 204 can be moved synchronously, so that regions of the reticle 203 are imaged onto corresponding regions of the wafer 204 virtually continuously during what is called a scanning operation.

An air gap between the last lens element 207 and the wafer 204 can optionally be replaced by a liquid medium which has a refractive index of greater than 1.0. The liquid medium can be, for example, high-purity water. Such a construction is also referred to as immersion lithography and has an increased photolithographic resolution.

The use of the invention is not restricted to use in projection exposure apparatuses 100, 200, in particular also not with the described construction. The invention is suitable for any desired lithography systems or microlithography systems, but in particular for projection exposure apparatuses having the described construction. The invention is also suitable for EUV projection exposure apparatuses which have a smaller image-side numerical aperture than that described in connection with FIG. 1, and have no obscured mirror M5 and/or M6. In particular, the invention is also suitable for EUV projection exposure apparatuses which have an image-side numerical aperture from 0.25 to 0.5, preferably 0.3 to 0.4, particularly preferably 0.33. The invention and the subsequent exemplary embodiments should also not be understood as being restricted to a specific design.

The figures that follow illustrate the invention merely by way of example and in highly schematized form.

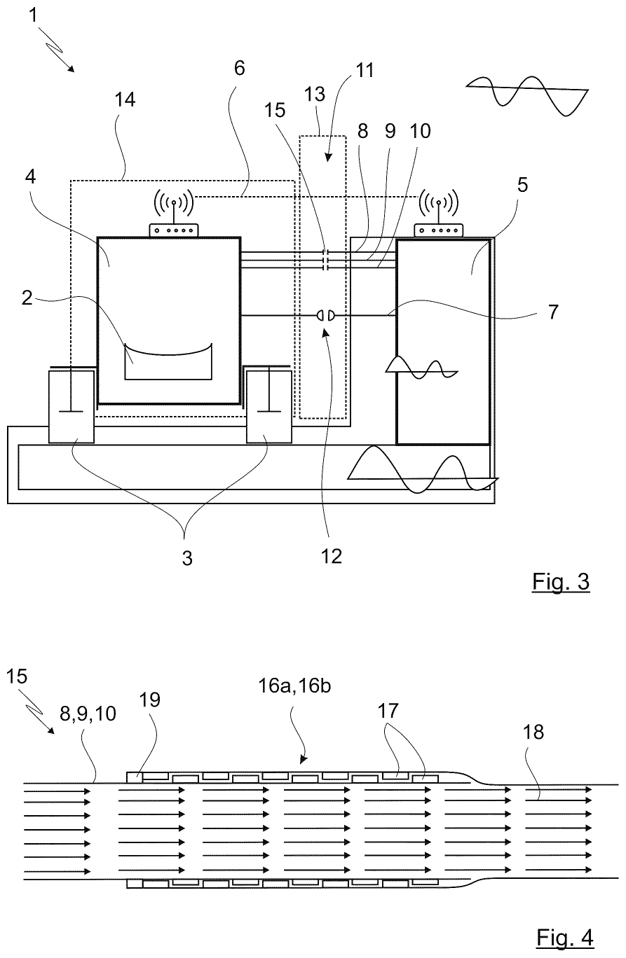

FIG. 3 shows a schematic illustration of a feasible embodiment of an apparatus 1 for measuring a component 2, in particular an optical component 2 of a lithography system. The optical component 2 may in particular be the collector 116 or one of the mirrors or one of the facets 118, 119, 120, 121, 122, Mi or one of the lens elements 207. The apparatus 1 comprises at least one vibration isolator device 3, a measuring system 4 mounted on the at least one vibration isolator device 3 and a supply device 5 for supplying the measuring system 4. In the case of the apparatus 1, the measuring system 4 is supplied via at least one data connection 6 for transferring data between the supply device 5 and the measuring system 4 and/or one current connection 7 for transferring electrical energy between the supply device 5 and the measuring system 4 and/or one gas connection 8 for transferring at least one gas between the supply device 5 and the measuring system 4 and/or one liquid connection 9 for transferring at least one liquid between the supply device 5 and the measuring system 4 and/or one vacuum connection 10 for transferring a vacuum between the supply device 5 and the measuring system 4.

In the case of the apparatus 1, a decoupling device 11 is provided and configured to mechanically at least partially decouple the measuring system 4 from the supply device 5 at least during the measurement of the component 2.

In the exemplary embodiment illustrated in FIG. 3, the decoupling device 11 is preferably configured to form an at least partially, preferably completely, wireless construction of the data connection 6. In FIG. 3, the wireless data connection 6 is symbolized by antennae on the supply device 5 and/or the measuring system 4.

In the exemplary embodiment illustrated in FIG. 3, the decoupling device 11 preferably has an induction device 12 which can be used to inductively transfer the electrical energy contactlessly at at least one point of the current connection 7.

According to the exemplary embodiment illustrated in FIG. 3, the decoupling device 11 is preferably arranged in an interface region 13 between the supply device 5 and the measuring system 4. In the schematic illustration according to FIG. 3, the interface region 13 is symbolized by a rectangle depicted in dashed form.

In the exemplary embodiment illustrated in FIG. 3, the measuring system 4 is further preferably arranged in an isolation box 14, which protects the measuring system 4 against the influence of airborne sound. In FIG. 3, the isolation box 14 is symbolized by a rectangle depicted in dashed form.

In the exemplary embodiment illustrated in FIG. 3, the decoupling device 11 has in each case contact-free transfer devices 15 for the gas connection 8 and/or the liquid connection 9 and/or the vacuum connection 10.

In particular, the transfer device 15 may be a contact-free seal which is explained below, in particular a gap seal 16a and/or a labyrinth seal 16b.

FIG. 4 shows a schematic illustration of a feasible embodiment of the transfer device 15 for the gas connection 8 and/or the liquid connection 9 and/or the vacuum connection 10.

In the exemplary embodiment illustrated in FIG. 4, the transfer device 15 is in the form of a gap seal 16a or labyrinth seal 16b. The labyrinth seal 16b has a meshing arrangement 17, in order to prevent the medium flowing in the connections 8, 9 and 10, which in FIG. 4 is symbolized by flow arrows 18, from flowing out.

Provision may preferably be made for the medium flow symbolized by the flow arrows 18 to be switched off or interrupted during a measuring operation of the apparatus 1. This can prevent disruptive flow noises, vibrations and structure-borne sound during the measurement.

In the exemplary embodiment illustrated in FIG. 4, the decoupling device 11 accordingly has a gap seal 16a and/or a labyrinth seal 16b which is arranged at at least one point of the gas connection 8 and/or of the liquid connection 9 and/or of the vacuum connection 10.

In the exemplary embodiment illustrated in FIG. 4, the gap seal 16a and/or the labyrinth seal 16b also have a sealing air device 19 for increasing the sealing effect. In the exemplary embodiment illustrated in FIG. 4, the sealing air device 19 has at least one nozzle element, in order to orient the sealing air at a suitable angle and with a suitable flow profile in relation to the gap and/or the labyrinth of the gap seal 16a and/or of the labyrinth seal 16b, respectively.

In the exemplary embodiment illustrated in FIG. 4, the sealing air device 19 is preferably configured for sealing-air suction removal.

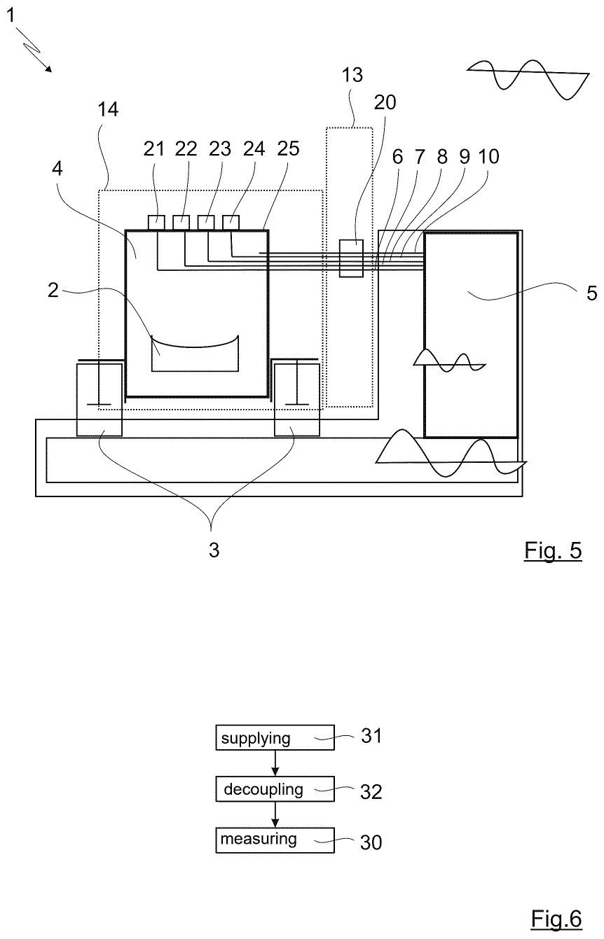

FIG. 5 shows a schematic illustration of a further feasible embodiment of the apparatus 1.

In the exemplary embodiment illustrated in FIG. 5, the decoupling device 11 preferably has an actuated movement mechanism 20.

According to the exemplary embodiment of the apparatus 1 illustrated in FIG. 5, the decoupling device 11 is configured to disconnect and/or to connect the data connection 6 and/or the current connection 7 and/or the gas connection 8 and/or the liquid connection 9 and/or the vacuum connection 10.

In the specific exemplary embodiment of the apparatus 1 illustrated in FIG. 5, the movement mechanism 20 is configured to preferably rapidly disconnect and/or connect the data connection 6 and/or the current connection 7 and/or the gas connection 8 and/or the liquid connection 9 and/or the vacuum connection 10.

Furthermore, according to the exemplary embodiment of the apparatus 1 illustrated in FIG. 5, the decoupling device 11 has at least one data carrier 21 and/or at least one electrical charge storage unit 22 and/or at least one gas storage unit 23 and/or at least one liquid container 24 and/or at least one vacuum accumulator device 25. In the specific exemplary embodiment illustrated in FIG. 5, the vacuum accumulator device 25 is realized by a vacuum-tight housing of the measuring system 4, which is sufficiently tight to maintain a vacuum environment at least for the duration of a measurement.

In the exemplary embodiment of the apparatus 1 illustrated in FIG. 5, the data connection 6 and/or the current connection 7 and/or the gas connection 8 and/or the liquid connection 9 and/or the vacuum connection 10 preferably have such a low stiffness that transmission of vibrations from the supply device 5 to the measuring system 4 is suppressed. This is advantageous in particular if disconnection of the connection during the measurement is not provided.

Preferably, in the exemplary embodiment of the apparatus 1 illustrated in FIG. 5, the data connection 6 and/or the current connection 7 and/or the gas connection 8 and/or the liquid connection 9 and/or the vacuum connection 10 have a stiffness of 0.1 N/mm to 100 N/mm, preferably 0.1 N/mm to 50 N/mm, further preferably 0.2 N/mm to 10 N/mm, in particular 0.2 N/mm to 2 N/mm.

In FIGS. 3 and 5, mechanical oscillations or vibrations which can emanate from the supply device 5, the ground and/or air or can be transmitted by them are illustrated as stylized waves.

FIG. 6 shows a block diagram-like illustration of a feasible embodiment of a method for measuring the component 2.

In the method, illustrated in FIG. 6, for measuring a component 2, in particular an optical component 2 of a lithography system, in a measuring block 30 the component 2 is measured using the measuring system 4 mounted in a vibration-damped manner. In a supply block 31, the supply device 5 supplies the measuring system 4 via the at least one data connection 6 for transferring data between the supply device 5 and the measuring system 4 and/or the at least one current connection 7 for transferring electrical energy between the supply device 5 and the measuring system 4 and/or via the at least one gas connection 8 for transferring at least one gas between the supply device 5 and the measuring system 4 and/or the at least one liquid connection 9 for transferring at least one liquid between the supply device 5 and the measuring system 4 and/or the at least one vacuum connection 10 for transferring a vacuum between the supply device 5 and the measuring system 4. In a decoupling block 32, the measuring system 4 is mechanically at least partially decoupled from the supply device 5 at least during the measurement of the component 2.

In the exemplary embodiment illustrated in FIG. 6, data are preferably transferred wirelessly via the data connection 6 in the context of the supply block 31 and/or the decoupling block 32.

Furthermore, in the context of the decoupling block 32 and/or the measuring block 30, the electrical energy is preferably transferred at least partially contactlessly, in particular inductively, via the current connection 7.

In the context of the supply block 31 and/or the decoupling block 32, in the exemplary embodiment illustrated in FIG. 6, the at least one gas and/or the at least one liquid and/or the vacuum is preferably transferred at at least one point of the gas connection 8 and/or of the liquid connection 9 and/or of the vacuum connection 10 via the gap seal 16a and/or the labyrinth seal 16b preferably at least approximately contactlessly, preferably contactlessly.

In the context of the decoupling block 32 of the exemplary embodiment of the method illustrated in FIG. 6, provision may be made for the data connection 6 and/or the current connection 7 and/or the gas connection 8 and/or the liquid connection 9 and/or the vacuum connection 10 to be disconnected before the measurement of the component 2 and/or reconnected after the measurement of the component 2.

In the exemplary embodiment illustrated in FIG. 6, in the context of the measuring block 30, the measuring system 4 can preferably during a measurement of the component 2 be operated partially or completely autonomously.

In the exemplary embodiment illustrated in FIG. 6, in the context of the supply block 31 and/or the decoupling block 32, before the measurement of the component 2, preferably the at least one data carrier 21 and/or the at least one electrical charge storage unit 22 and/or the at least one gas storage unit 23 and/or the at least one liquid container 24 and/or the at least one vacuum accumulator device 25 can be loaded via the data connection 6 and/or the current connection 7 and/or the gas connection 8 and/or the liquid connection 9 and/or the vacuum connection 10.

In the exemplary embodiment illustrated in FIG. 6, in the context of the supply block 31, during the measurement of the component 2, the measuring system 4 is preferably supplied at least partially by the data carrier 21 and/or the electrical charge storage unit 22 and/or the gas storage unit 23 and/or the liquid container 24 and/or the vacuum accumulator device 25.

FIGS. 1 and 2 show lithography systems, in particular projection exposure apparatuses 100, 200 for semiconductor lithography, having an illumination system 101, 201 and having a radiation source 102 and an optical unit 103, 109, 206 which has at least one optical component 116, 118, 119, 120, 121, 122, Mi, 207.

In the case of the projection exposure apparatuses 100, 200 illustrated in FIGS. 1 and 2, at least one of the optical components 116, 118, 119, 120, 121, 122, Mi, 207 is measured at least partially using the apparatus 1 outlined in connection with FIGS. 3 to 5 and/or is measured at least partially using the method outlined in connection with FIG. 6.

The component 2 measured with the apparatus 1 and/or the method described in connection with FIG. 6 is accordingly preferably one of the optical components 116, 118, 119, 120, 121, 122, Mi, 207 in the case of the projection exposure apparatus 100, 200 illustrated in FIGS. 1 and 2.

The apparatus 1 according to the invention and the described method according to the invention are particularly suitable for the mirrors Mi.

A second aspect of the invention is illustrated in principle below, with reference to FIG. 3. In the second aspect of the invention, provision is made for the apparatus 1 or a corresponding method to be used for the lithography system itself. In the second aspect of the invention, the lithography system constitutes the measuring system 4, as is shown by example in FIG. 3. It is only for the description of the second aspect of the invention that the reference sign 4, with reference to FIG. 3, is used below for the lithography system. The subsequent statements apply correspondingly to the method for implementing the second aspect of the invention. According to the second aspect of the invention, provision is made for the apparatus 1 to be used for a lithography system 4 having at least one vibration isolator device 3 or for the lithography system to be part of the apparatus 1. Provision is made for the lithography system 4 to be mounted on the at least one vibration isolator device 3. Furthermore, a supply device 5 for supplying the lithography system 4 is provided. The supply is effected via at least one data connection 6 for transferring data between the supply device 5 and the lithography system 4 and/or one current connection 7 for transferring electrical energy between the supply device 5 and the lithography system 4 and/or one gas connection 8 for transferring at least one gas between the supply device 5 and the lithography system 4 and/or one liquid connection 9 for transferring at least one liquid between the supply device 5 and the lithography system 4 and/or one vacuum connection 10 for transferring a vacuum between the supply device 5 and the lithography system 4. A decoupling device 11 is provided and configured to mechanically at least partially decouple the lithography system 4 from the supply device 5 at least during a predefinable operation, for example during maintenance or during operation or during an adjustment. The lithography system 4 may also concern only a component of the lithography system 4, in particular a projection system or an illumination optical unit 103 or an exposure system or the illumination system 101. The second aspect of the invention is associated with the idea that an apparatus according to the invention and a method according to the invention for measuring a component can also be used for the lithography system itself and not only for measuring a component which is subsequently inserted in the lithography system.

### LIST OF REFERENCE SIGNS

1 Apparatus
2 Component
3 Vibration isolator device
4 Measuring system
5 Supply device
6 Data connection
7 Current connection
8 Gas connection
9 Liquid connection
10 Vacuum connection
11 Decoupling device
12 Induction device
13 Interface region
14 Isolation box
15 Transfer device
16a Gap seal
16b Labyrinth seal
17 Meshing arrangement
18 Flow arrow
19 Sealing air device
20 Movement mechanism
21 Data carrier
22 Charge storage unit
23 Gas storage unit
24 Liquid container
25 Vacuum accumulator device
30 Measuring block
31 Supply block
32 Decoupling block
100 EUV projection exposure apparatus
101 Illumination system
102 Radiation source
103 Illumination optical unit
104 Object field
105 Object plane
106 Reticle
107 Reticle holder
108 Reticle displacement drive
109 Projection optical unit
110 Image field
111 Image plane
112 Wafer
113 Wafer holder
114 Wafer displacement drive
115 EUV/used/illumination radiation
116 Collector
117 Intermediate focal plane
118 Deflection mirror
119 First facet mirror/field facet mirror
120 First facets/field facets
121 Second facet mirror/pupil facet mirror
122 Second facets/pupil facets
200 DUV projection exposure apparatus
201 Illumination system
202 Reticle stage
203 Reticle
204 Wafer
205 Wafer holder
206 Projection optical unit
207 Lens element
208 Mount
209 Lens housing
210 Projection beam
Mi Mirror

What is claimed is:

1. An apparatus for measuring a component, comprising:
at least one vibration isolator device,
a measuring system mounted on the at least one vibration isolator device,
a supply device for supplying the measuring system via at least
one data connection for transferring data between the supply device and the measuring system and/or
one current connection for transferring electrical energy between the supply device and the measuring system and/or
one gas connection for transferring at least one gas between the supply device and the measuring system and/or
one liquid connection for transferring at least one liquid between the supply device and the measuring system and/or
one vacuum connection for transferring a vacuum between the supply device and the measuring system, and
a decoupling device configured to mechanically at least partially decouple the measuring system from the supply device at least during the measurement of the component.

2. The apparatus as claimed in claim 1,
wherein
the decoupling device is further configured to form an at least partially wireless construction of the data connection.

3. The apparatus as claimed in claim 1,
wherein
the decoupling device comprises an induction device configured to inductively transfer the electrical energy contactlessly at at least one point of the current connection.

4. The apparatus as claimed in claim 1,
wherein
the decoupling device comprises a gap seal and/or a labyrinth seal which is arranged at at least one point of the gas connection and/or of the liquid connection and/or of the vacuum connection.

5. The apparatus as claimed in claim 4,
wherein
the gap seal and/or the labyrinth seal comprises a sealing air device arranged to increase the sealing effect.

6. The apparatus as claimed in claim 1,
wherein
the decoupling device is arranged in an interface region between the supply device and the measuring system.

7. The apparatus as claimed in claim 1,
wherein
the decoupling device comprises an actuated movement mechanism.

8. The apparatus as claimed in claim 1,
wherein
the decoupling device is further configured to disconnect and/or to connect the data connection and/or the current connection and/or the gas connection and/or the liquid connection and/or the vacuum connection.

9. The apparatus as claimed in claim 1,
wherein
the decoupling device comprises at least one data carrier and/or at least one electrical charge storage unit and/or at least one gas storage unit and/or at least one liquid container and/or at least one vacuum accumulator device.

10. The apparatus as claimed in claim 1,
wherein
the data connection and/or the current connection and/or the gas connection and/or the liquid connection and/or the vacuum connection has a sufficiently low stiffness that transmission of vibrations from the supply device to the measuring system is at least largely suppressed.

11. The apparatus as claimed in claim 1,
wherein
the data connection and/or the current connection and/or the gas connection and/or the liquid connection and/or the vacuum connection has a stiffness of 0.1 N/mm to 100 N/mm.

12. The apparatus as claimed in claim 11,
wherein
the data connection and/or the current connection and/or the gas connection and/or the liquid connection and/or the vacuum connection has a stiffness of 0.2 N/mm to 2 N/mm.

13. A method, comprising:
measuring a component using a measuring system mounted in a vibration-damped manner, wherein a supply device supplies the measuring system via at least
one data connection for transferring data between the supply device and the measuring system and/or
one current connection for transferring electrical energy between the supply device and the measuring system and/or
one gas connection for transferring at least one gas between the supply device and the measuring system and/or
one liquid connection for transferring at least one liquid between the supply device and the measuring system and/or
one vacuum connection for transferring a vacuum between the supply device and the measuring system, and
mechanically decoupling the measuring system at least partially from the supply device at least during said measuring of the component.

14. The method as claimed in claim 13,
further comprising
transferring the data wirelessly via the data connection.

15. The method as claimed in claim 13,
further comprising
transferring the electrical energy at least partially inductively via the current connection.

16. The method as claimed in claim 13,
further comprising
transferring the at least one gas and/or the at least one liquid and/or the at least one vacuum at at least one point of the gas connection and/or of the liquid connection and/or of the vacuum connection via a gap seal and/or a labyrinth seal.

17. The method as claimed in claim 13,
further comprising
disconnecting the data connection and/or the current connection and/or the gas connection and/or the liquid connection and/or the vacuum connection before said measuring of the component and/or
reconnecting the data connection and/or the current connection and/or the gas connection and/or the liquid connection and/or the vacuum connection after said measuring of the component.

18. The method as claimed in claim 13,
further comprising
operating the measuring system partially or completely autonomously during said measuring of the component.

19. The method as claimed in claim 13,
further comprising,
before said measuring of the component, loading at least one data carrier and/or at least one electrical charge storage unit and/or at least one gas storage unit and/or at least one liquid container and/or at least one vacuum accumulator device via the data connection and/or the current connection and/or the gas connection and/or the liquid connection and/or the vacuum connection.

20. The method as claimed in claim 19,
further comprising,
during said measuring of the component, supplying the measuring system at least partially by the data carrier and/or the electrical charge storage unit and/or the gas storage unit and/or the liquid container and/or the vacuum accumulator device.

21. A lithography system, comprising:
an illumination system with a radiation source and an optical unit having at least one optical component
wherein
the at least one optical component is at least partially measured with the method as claimed in claim 13.

22. The lithography system as claimed in claim 21, comprising a projection exposure apparatus for semiconductor lithography.
